(19) United States
(12) Patent Application Publication
(10) Pub. No.: US 2013/0248814 A1
(43) Pub. Date: Sep. 26, 2013

(54) NON-VOLATILE MEMORY DEVICE AND ARRAY THEREOF

(71) Applicants: Tuo-Hung Hou, Hsinchu City (TW); Jiun-Jia Huang, Yunlin County (TW)

(72) Inventors: Tuo-Hung Hou, Hsinchu City (TW); Jiun-Jia Huang, Yunlin County (TW)

(73) Assignee: WINBOND ELECTRONICS CORP., Taichung City (TW)

(21) Appl. No.: 13/424,380

(22) Filed: Mar. 20, 2012

(51) Int. Cl. H01L 45/00; H01L 27/24

(52) U.S. Cl. 257/5; 257/2; 257/E45.003; 257/E27.004

(57) ABSTRACT

A non-volatile memory device including a first electrode, a resistor structure, a diode structure, and a second electrode is provided. The resistor structure is disposed on the first electrode. The resistor structure includes a first oxide layer. The first oxide layer is disposed on the first electrode. The diode structure is disposed on the resistor structure. The diode structure includes a metal layer and a second oxide layer. The metal layer is disposed on the first oxide layer. The second oxide layer is disposed on the metal layer. The second electrode is disposed on the diode structure. A material of the metal layer is different from that of the second electrode. Furthermore, a non-volatile memory array including the foregoing memory devices is also provided.

### BACKGROUND

1. Technical Field

The invention relates to an electronic device and an array thereof. More particularly, the invention relates to a non-volatile memory device and an array thereof.

2. Related Art

Recently, resistive-switching random access memory (RRAM) has been explored for non-volatile memory (NVM) applications, owing to its simple crossbar array architecture and low-temperature fabrication. The crossbar array architecture is designed based on a resistive-switching (RS) element concept that theoretically allows the smallest cell size of 4F², wherein F denotes a feature size. Therefore, a crossbar non-volatile memory array may have an unprecedented high integration density.

FIG. 1 is a schematic diagram illustrating the concept of a cell size. In FIG. 1, a non-volatile memory array is composed by a plurality of bit lines BL and a plurality of word lines WL, and memory cells are located at cross-points of the bit lines BL and word lines WL. The cell size (i.e. the area occupied) of each memory cell is approximately 4F². Therefore, in order to achieve the integration density of 1 terabyte/cm², a condition of F=5 nm must first be fulfilled. In the prior art, such high integration density is difficult to achieve if each of the memory cells includes a transistor architecture.

However, the crossbar non-volatile memory array mentioned above still has some drawbacks, such as problems associated with sneak current. FIG. 2A is a schematic diagram illustrating a theoretical read status of the memory cells in a portion of the non-volatile memory array. FIG. 2B is a schematic diagram illustrating an actual read status of the memory cells in FIG. 2A, in which the problem of sneak current may exist. Referring to FIG. 2A and FIG. 2B, with regard to the read status of the memory cells as illustrated in FIG. 2A, a specific read voltage is applied to the selected word line and the selected bit line to read the bit value. In this example, a read voltage Vread is applied to the selected word line WL2, and the voltage value of the selected bit line BL2 is 0. Since the selected memory cell at lower right is in “off” status, theoretically the expected read resistance is a larger resistance value, which corresponds to a smaller read current value. However, since the neighboring unselected memory cells are in “on” status, a sneak current path P_{SC} may exist at actual read. The existence of said path forces the sneak current to flow through the word line WL2 and the bit line BL2 along the neighboring memory cells. In this case, the read current value increases and significantly deteriorates the read margin, causing a false bit status read.

### SUMMARY

The invention provides a non-volatile memory device and an array thereof to reduce internal sneak current and avoid false bit status read.

The invention provides a non-volatile memory device including a first electrode, a resistor structure, a diode structure, and a second electrode. A resistor structure is disposed on the first electrode, and the resistor structure includes a first oxide layer. The first oxide layer is disposed on the first electrode. The diode structure is disposed on the resistor structure. The diode structure includes a first metal layer and a second oxide layer. The first metal layer is disposed on the first oxide layer. The second oxide layer is disposed on the first metal layer. The second electrode is disposed on the diode structure. A material of the first metal layer is different from a material of the second electrode.

The invention provides a non-volatile memory array including a memory cell array, a plurality of bit lines, and a plurality of word lines. The non-volatile memory cell array includes a plurality of non-volatile memory devices. Each of the non-volatile memory devices has a first end and a second end. Each of the non-volatile memory devices includes a resistor structure and a diode structure. The resistor structure and the diode structure are vertically stacked in series and coupled between the first end and the second end of each non-volatile memory device. Each of the bit lines is used as a first electrode and coupled with the first ends of the corresponding non-volatile memory devices. Each of the word lines is used as a second electrode and coupled with the second ends of the corresponding non-volatile memory devices. The non-volatile memory devices are disposed at the cross-points of the bit lines and the word lines. With regard to each of the plurality of non-volatile memory devices, the resistor structure includes a first oxide layer. The first oxide layer is disposed on the corresponding first electrode. The diode structure includes a first metal layer and a second oxide layer. The first metal layer is disposed on the first oxide layer. The second oxide layer is disposed on the first metal layer. The corresponding second electrode is disposed on the second oxide layer. A material of the first metal layer is different from a material of the second electrode.

Based on the above, in the exemplary embodiments of the invention, the non-volatile memory devices belongs to a one-diode-one-resistor (1D1R) structure, which is vertically stacked in series at the cross-point of the word line and the bit line in the memory array for reducing the internal sneak current.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating the concept of a cell size.

FIG. 2A is a schematic diagram illustrating a theoretical read status of the memory cells in a portion of the non-volatile memory array.

FIG. 2B is a schematic diagram illustrating an actual read status of the memory units in FIG. 2A.

FIG. 3 is a three-dimensional schematic diagram illustrating a non-volatile memory array of an embodiment of the invention.

FIG. 4A is a schematic diagram illustrating a stacking structure of the non-volatile memory device in FIG. 3.

FIG. 4B is an equivalent circuit diagram illustrating the non-volatile memory device in FIG. 4A.

FIG. 5 is a diagram illustrating a read status of the memory cells in a portion of the non-volatile memory array according to an embodiment of the invention.

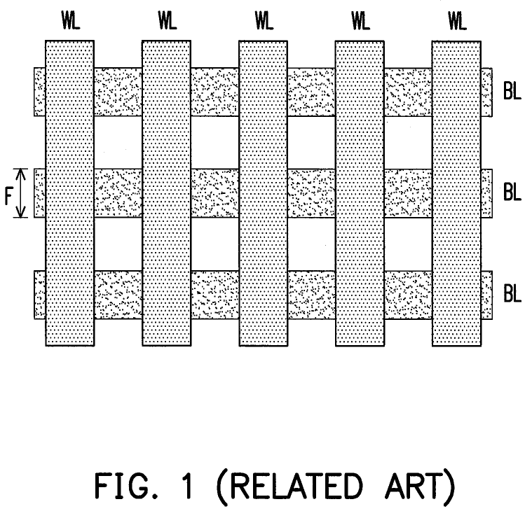

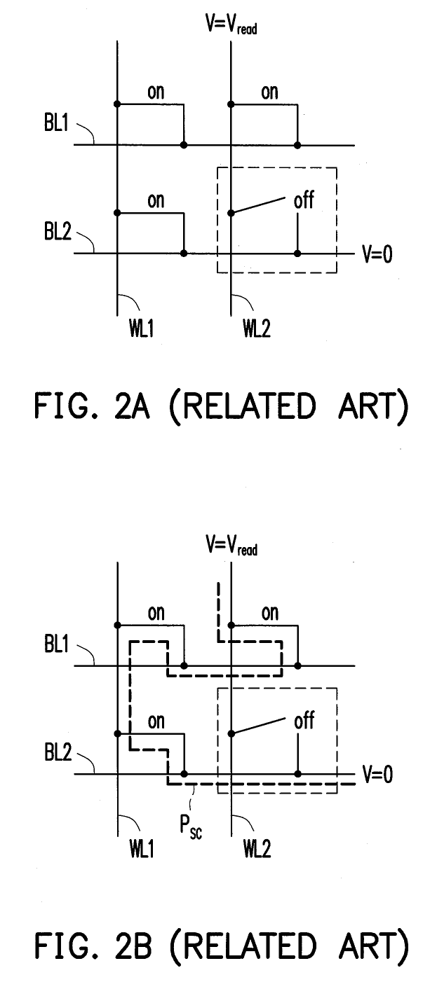

### DETAILED DESCRIPTION OF DISCLOSED EMBODIMENTS

In an exemplary embodiment of the invention, the problem of sneak current can be solved by adding a nonlinear element in series with the internal resistor element to the memory cell. The nonlinear element is, for example, a unipolar diode, connected with a unipolar resistor element in series to increase the nonlinearity of the low-resistance status resistance, and an architecture of 1D1R cell is applied as an example in an exemplary embodiment of the invention. Furthermore, to maintain a smallest cell size of 4F², the diode element and the resistor element can be vertically stacked in order to connect each other in series. Accordingly, the vertical stacking method can easily be applied to the non-volatile memory with high density.

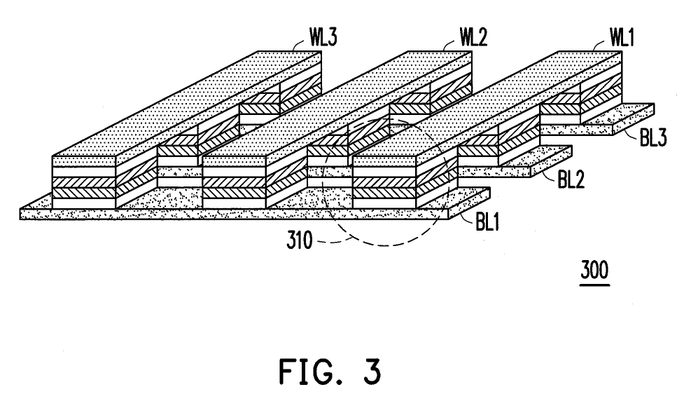

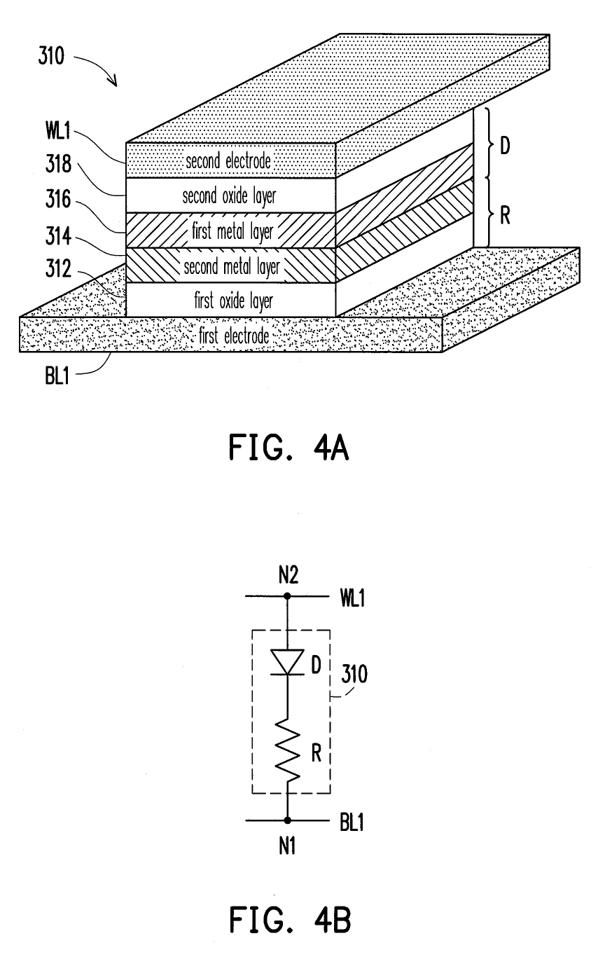

An exemplary embodiment is described below to illustrate the invention in detail. FIG. 3 is a three-dimensional schematic diagram illustrating a non-volatile memory array of an embodiment of the invention. FIG. 4A is a schematic diagram illustrating a stacking structure of the non-volatile memory device in FIG. 3. FIG. 4B is an equivalent circuit diagram illustrating the non-volatile memory device in FIG. 4A. Referring to FIG. 3 to FIG. 4B, a non-volatile memory array 300 includes a memory cell array, a plurality of bit lines BL1 to BL3 and a plurality of word lines WL1 to WL3. The memory cell array includes a plurality of non-volatile memory devices respectively disposed at the cross-point of each bit line and each word line.

For example, the non-volatile memory device 310 is disposed at the cross-point of the bit line BL1 and the word line WL1. The non-volatile memory device 310 has a first end N1 and a second end N2, as shown in FIG. 4B. The first end N1 is a connecting point of the non-volatile memory device 310 and the bit line BL1, and the bit line BL1 is used as the first electrode of the non-volatile memory device 310. The second end N2 is a connecting point of the non-volatile memory device 310 and the word line WL1, and the word line WL1 is used as the second electrode of the non-volatile memory device 310. The coupling relations of the other non-volatile memory devices with the bit lines and the word lines thereof may be deduced by analogy, so it will not be described herein. Therefore, in the present embodiment, the bit lines BL1 to BL3 and the word lines WL1 to WL3 are respectively coupled to the first end N1 and the second end N1 of the corresponding non-volatile memory device. In FIG. 3, the amounts of the bit lines BL1 to BL3, the word lines WL1 to WL3 and the non-volatile memory device 310 in the non-volatile memory array 300 are only used as examples, and the invention is not thereby limited.

On the other hand, referring to FIG. 4A, the non-volatile memory device 310 includes a resistor structure R and a diode structure D. The resistor structure R and the diode structure D are vertically stacked in series and coupled between the first end N1 and the second end N2 of the non-volatile memory device 310. In the present embodiment, the resistor structure R includes a first oxide layer 312. The first oxide layer 312 is disposed on the bit line BL1, which is used as a first electrode. Herein, a material of the first electrode may be a metal such as Pt; and a material of the first oxide layer 312 may be an oxide selected from the group consisting of NiO, TiO₂, HfO, HfO₂, ZrO, ZrO₂, Ta₂O₅, ZnO, WO₃, CoO and Nb₂O₅, for example.

In another aspect, the first electrode and the resistor structure are used as a resistance-switching element of the non-volatile memory device 310. The first oxide layer 312 is a data storage layer for the non-volatile memory device 310.

In the present embodiment, the diode structure D is stacked on the resistor structure R. The diode structure D comprises a first metal layer 316 and a second oxide layer 318. The first metal layer 316 is disposed on the first oxide layer 312. The second oxide layer 318 is disposed on the first metal layer 316. The word line WL1 is used as the second electrode and disposed on the second oxide layer 318. Note that a material of the first metal layer 316 is different from a material of the second electrode. Herein, a material of the first metal layer 316 may be a metal such as Ti; a material of the second electrode may be a metal such as Pt; and a material of the second oxide layer 318 may be an oxide selected from the group consisting of NiO, TiO₂, HfO, HfO₂, ZrO, ZrO₂, Ta₂O₅, ZnO, WO₃, CoO and Nb₂O₅, for example. Furthermore, in the present embodiment, the resistor structure R may optionally includes a second metal layer 314. The second metal layer 314 is disposed on the first oxide layer 312, and a material of the second metal layer 314 is N1, for example. Herein, the first metal layer 316 is disposed on the second metal layer 314.

In another aspect, an metal-insulator-metal (MIM) diode of the non-volatile memory device 310 is formed by the second electrode, the second oxide layer 318 and the first metal layer 316. The second oxide layer 318 and the first metal layer 316 are used as a p-n junction of the diode for suppressing the internal sneak current in the non-volatile memory array 300, and this will be described in more detail below.

An exemplary embodiment of non-volatile memory device in the invention is described hereinafter, regarding how to avoid internal sneak current from being generated in the array.

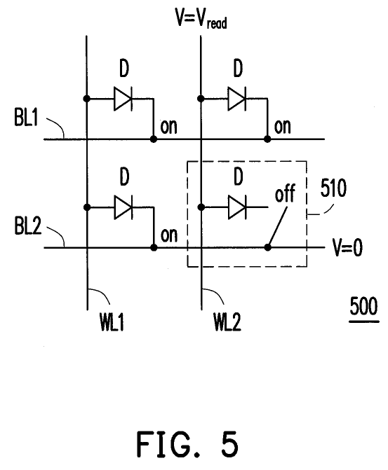

FIG. 5 is a diagram illustrating a read status of memory cells in a portion of the non-volatile memory array according to an embodiment of the invention. Referring to FIG. 5, the vertical stacking structure of each memory device in the non-volatile memory array 500 of the present embodiment is as shown in FIG. 4A. In FIG. 5, each of the non-volatile memory devices is disposed at the cross-point of the word line and the bit line. The non-volatile memory device includes an MIM diode coupled in series with the resistance-switching element in between the word line and the bit line. An anode of each diode is coupled with a respective word line, and a cathode of each diode is coupled with a respective bit line.

In the present embodiment, a read voltage Vread is applied to the selected word line WL2, and the voltage value of the bit line BL2 is 0. During actual read, the MIM diode of the non-volatile memory device at upper left is a unipolar diode for blocking the sneak current path at read, so that the sneak current cannot flow through the word line WL2 and the bit line BL2 along the memory cells of the neighboring non-volatile memory device 510. Therefore, in comparison with the prior art, the read current value is not affected by the sneak current, and false bit status read can be avoided. It should be noted that, the read status from the memory cells shown in FIG. 5 is only used as an example, and the invention is not thereby limited. With respect to other read status in the non-volatile memory array, since each of the memory cells includes a unipolar MIM diode, the theory of blocking the sneak current thereto may be deduced by analogy, so it will not be described herein.

In summary, in the exemplary embodiment of the invention, the non-volatile memory array includes a 1D1R memory device structure, which is vertically stacked in series at the cross-point of the word line and the bit line in the memory array for reducing the internal sneak current. Furthermore, the diode element and the resistor element are stacked vertically for maintaining a smaller cell size.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

1. A non-volatile memory device, comprising:
a first electrode;
a resistor structure, disposed on the first electrode, the resistor structure comprising:
a first oxide layer, disposed on the first electrode; and
a diode structure, disposed on the resistor structure, the diode structure comprising:
a first metal layer, disposed on the first oxide layer; and
a second oxide layer, disposed on the first metal layer; and
a second electrode, disposed on the diode structure,
wherein a material of the first metal layer is different from a material of the second electrode, and the resistor structure further comprises a second metal layer disposed on the first oxide layer, wherein the first metal layer is disposed on the second metal layer.

2. (canceled)

3. The non-volatile memory device of claim 1, wherein a material of the first metal layer is different from a material of the second metal layer.

4. The non-volatile memory device of claim 1, wherein a material of the first metal layer is the same as a material of the second metal layer.

5. The non-volatile memory device of claim 1, wherein the first oxide layer is a data storage layer for the non-volatile memory device, the material of the first oxide layer is an oxide selected from the group consisting of NiO, TiO₂, HfO, HfO₂, ZrO, ZrO₂, Ta₂O₅, ZnO, WO₃, CoO and Nb₂O₅; and the material of the second oxide layer is an oxide selected from the group consisting of NiO, TiO₂, HfO, HfO₂, ZrO, ZrO₂, Ta₂O₅, ZnO, WO₃, CoO and Nb₂O₅.

6. A non-volatile memory array, comprising:
a memory cell array, comprising a plurality of non-volatile memory devices, each of the non-volatile memory devices has a first end and a second end, and each of the non-volatile memory devices comprises a resistor structure and a diode structure, the resistor structure and the diode structure are vertically stacked in series and coupled between the first end and the second end of each of the non-volatile memory devices;
a plurality of bit lines, each of the bit lines is used as a first electrode and coupled with the first ends of the corresponding non-volatile memory devices; and
a plurality of word lines, each of the word lines is used as a second electrode and coupled with the second ends of the corresponding non-volatile memory devices, wherein the non-volatile memory devices are disposed at the cross-points of the plurality of bit lines and the plurality of word lines,
wherein, with regard to each of the non-volatile memory devices, the resistor structure comprises a first oxide layer, the first oxide layer is disposed on the corresponding first electrode; and the diode structure comprises a first metal layer and a second oxide layer, the first metal layer is disposed on the first oxide layer, the second oxide layer is disposed on the first metal layer, the corresponding second electrode is disposed on the second oxide layer, wherein a material of the first metal layer is different from a material of the second electrode, and the resistor structure further comprises a second metal layer disposed on the first oxide layer, wherein the first metal layer is disposed on the second metal layer.

7. (canceled)

8. The non-volatile memory array of claim 1, wherein with regard to each of the non-volatile memory devices, a material of the first metal layer is different from a material of the second metal layer.

9. The non-volatile memory array of claim 1, wherein, with regard to each of the non-volatile memory devices, a material of the first metal layer is the same as a material of the second metal layer.

10. The non-volatile memory array of claim 6, wherein, with regard to each of the non-volatile memory devices, the first oxide layer is a data storage layer for the non-volatile memory device, the material of the first oxide layer is an oxide selected from the group consisting of NiO, TiO₂, HfO, HfO₂, ZrO, ZrO₂, Ta₂O₅, ZnO, WO₃, CoO and Nb₂O₅, and the material of the second oxide layer is an oxide selected from the group consisting of NiO, TiO₂, HfO, HfO₂, ZrO, ZrO₂, Ta₂O₅, ZnO, WO₃, CoO and Nb₂O₅.
